(19) United States
(12) Patent Application Publication
(10) Pub. No.: US 2024/0418784 A1
(43) Pub. Date: Dec. 19, 2024

(54) Battery Monitoring Apparatus and Battery Pack

(71) Applicant: Clean Republic SODO LLC, Seattle, WA (US)

(72) Inventor: Michael S. Shope, Seattle, WA (US)

(73) Assignee: Clean Republic SODO LLC, Seattle, WA (US)

(21) Appl. No.: 18/735,688

(22) Filed: Jun. 6, 2024

Related U.S. Application Data
(60) Provisional application No. 63/509,025, filed on Jun. 19, 2023.

(51) Int. Cl. G01R 31/382; H01M 10/42; H01M 50/284; H01M 50/569

(52) U.S. Cl. CPC G01R 31/382; H01M 10/425; H01M 50/284; H01M 50/569; H01M 2010/4271; H01M 2010/4278

(57) ABSTRACT

The present invention is directed to a battery monitoring apparatus useful for monitoring a variety of battery parameters. The battery monitoring apparatus comprises a battery pack, a set of sense wires, and a printed circuit board operably connected to the set of sense wires. The printed circuit board may be positioned within the battery case or mounted externally as an accessory. The printed circuit board further comprises a memory, microprocessor, current measuring device, and wireless transmitter. The printed circuit board relays battery data to an external device and may be used in conjunction with a variety of battery management systems. The claimed battery monitoring apparatus is particularly advantageous to battery distributors seeking to create a standardized user experience for end users to monitor their battery performance data.

### CROSS REFERENCES TO RELATED APPLICATIONS

This application claims the benefit of U.S. Provisional Patent Application No. 63/509,025, filed Jun. 19, 2023, which is incorporated by reference herein in its entirety.

### BACKGROUND

The demand for electric vehicles and electronic products has increased dramatically in recent years, with consumers and businesses alike seeking to reduce their carbon footprint and increase their energy efficiency. Because batteries power these electric devices, monitoring the health, State of Charge (SoC), and other crucial parameters of the battery is of paramount importance. Furthermore, in the realm of Internet of Things (IoT), there has been a growing demand for intelligent, interconnected devices that offer real-time data access and analytics. As demand for batteries and IoT devices has grown, so has the need for effective systems that can monitor and manage the performance of the battery.

Batteries, being integral to a multitude of electronic devices, from electric vehicles to everyday gadgets, necessitate efficient management to ensure their optimal operation and longevity. Traditional battery systems have often focused on basic functionalities like charging and discharging control. However, as technological advancements have surged and battery-operated devices have become more prevalent and complex, there is a rising demand for advanced battery management systems BMS(s) that can cater to diverse functionalities beyond mere charging control. Modern applications, particularly in electric vehicles, require advanced BMS functionality to ensure battery safety, optimize performance, predict failures, and extend battery life. Nonetheless, existing battery management solutions may lack comprehensive integration of these features, or may not offer real-time monitoring and analytics, leading to inefficiencies and potential risks in battery operation.

Some Bluetooth®-enabled BMS batteries indeed provide end-users with the ability to access and monitor battery performance data via a mobile or external device. However, these Bluetooth®-enabled BMS batteries are typically supplier-dependent, which can create challenges for battery distributors with multiple BMS supply chains. Each supplier may use a different proprietary Bluetooth® BMS system, making it difficult for distributors to provide Bluetooth BMS technology across a diverse product catalog.

Furthermore, some lithium-ion batteries may include a BMS but altogether lack the Bluetooth®-enabling technology necessary to transmit battery data to an end-user. As a result, end-users may be unable to monitor the performance of their batteries, which can limit their ability to optimize battery performance and extend battery life.

To address these challenges, there is a need for a BMS agnostic battery monitoring apparatus. This apparatus would be compatible with a wide range of batteries and BMS, providing end-users with a reliable and convenient means of monitoring battery performance data. The apparatus could be integrated into a wide range of applications, including electric vehicles, renewable energy systems, and consumer electronics products.

### SUMMARY

The present invention is directed to a BMS-agnostic battery monitoring apparatus—here forward referred to as ‘the apparatus’—that wirelessly transmits battery data to an external device. The apparatus compromises a set of sense wires and a printed circuit board (PCB) operably connected to a battery. The PCB comprises a memory connected to a microprocessor to execute computer-executable instructions, a memory connected to the microprocessor, current measuring sensor, and wireless transmitter. The PCB may be mounted either externally or internally to the battery case.

The memory connected to the microprocessor stores computer-readable instructions, historic voltage information, lifetime charge-and-discharge cycles, and identifying information of the battery pack. The microprocessor executes computer-executable instructions and is configured to determine, from the sense wires and current measuring device, at least the following battery data: voltage, SoC, temperature, and instantaneous current. The microprocessor is operably connected to a plurality of sense wires to monitor and control the performance of the battery cells and is configured to generate information for controlling the charging, discharging, and balancing of each of the battery cells based on the calculated SoC and/or State of Health, determined from the raw battery data. The firmware flashed onto the microprocessor includes control loops and algorithms that use the sense data to adjust the output control signals and maintain the battery cells within safe and efficient operating limits. The wireless transmitter is configured to transmit battery data to an external device.

A number of wireless transmitters are envisioned, including Bluetooth® or wireless 802.11. The wireless transmitter is configured to transmit battery data from the battery monitoring apparatus to a remote device. The microcontroller may receive data from sense wires and a current measuring device, process the data, and prepare it for transmission over the Bluetooth® or wireless 802.11 connection. The microcontroller may also receive commands or instructions from a remote device via the Bluetooth® or wireless 802.11 connection and execute control logic on the instructions received. Said Bluetooth® or wireless 802.11 transmitter may include security and power-saving features to protect the data transmitted and conserve battery life.

The battery monitoring apparatus further comprises a current measuring device that is mounted directly onto the PCB. The current measuring device can measure the electrical current flowing through the battery pack and may illustratively be comprised of a shunt resistor, an operational amplifier, and an analog-to-digital converter (ADC). The shunt resistor(s) may be connected in series with the battery to measure the current, while the operational amplifier amplifies the voltage drop across the shunt resistor and provides a proportional output voltage to the ADC. The ADC converts the analog output voltage to a digital value that can be processed by the microprocessor. The device can be powered by the battery voltage, calibrated using a known current source or reference instrument, and includes power management features, such as sleep mode, to conserve power.

In one embodiment, a plurality of sense wires is connected to the individual battery cells and provides battery performance data to the microcontroller, including, but not limited to, battery voltage and temperature. The sense wires are connected to the PCB. The number of sense wires may vary depending on the size and complexity of the battery system, but typically includes one sense wire per cell or group of cells. The sense wires are connected using a reliable and secure connection method, which may involve soldering, crimping, or using another connector system. The sense wires may be arranged in a daisy-chain or star configuration and may be multiplexed to reduce the number of wires needed. Additionally, the sense wires may include balancing circuits and overvoltage/undervoltage protection circuits to ensure the safe and efficient operation of the battery system.

In an alternative embodiment, the PCB is mounted externally to the battery case. In such a configuration, the sense wires need not be connected to each battery cell. Rather, the sense wires will connect to the positive and negative terminal of the battery system.

The foregoing is a summary and thus contains, by necessity, simplifications, generalizations, and omissions of detail; consequently, those skilled in the art will appreciate that the summary is illustrative only and is not intended to be in any way limiting. Other aspects, inventive features, and advantages of the present invention will be apparent in the non-limiting detailed description set forth below.

### BRIEF DESCRIPTION OF THE DRAWINGS

The present invention may be better understood, and its numerous objects, features, and advantages made apparent to those skilled in the art by referencing the accompanying drawings, wherein:

FIG. 1 depicts a schematic overview of the battery monitoring apparatus, wherein the PCB is mounted inside of the battery case;

FIG. 2 is a top view of the PCB;

FIG. 3 depicts a schematic overview of the battery monitoring apparatus, wherein the PCB is mounted outside the battery case;

FIG. 4 illustrates the circuitry connecting the sense wires to the connection area on the PCB wherein the PCB is mounted internally on the battery case;

FIG. 5 depicts circuitry for a Hall Effect sensor;

FIG. 6 depicts circuitry for the microprocessor;

FIG. 7 depicts circuitry for a low dropout regulator;

FIG. 8 is a flowchart depicting PCB communication with an external device and server;

FIG. 9 depicts attributes of the PCB substrate itself.

### DETAILED DESCRIPTION

Hereinafter, preferred embodiments of the present disclosure will be described in detail with reference to the accompanying drawings. Prior to the description, it should be understood that the terms or words used in the specification and the appended claims should not be construed as limited to general and dictionary meanings, but interpreted based on the meanings and concepts corresponding to technical aspects of the present disclosure on the basis of the principle that the inventor is allowed to define terms appropriately for the best explanation.

Therefore, the embodiments described herein and illustrations shown in the drawings are just a most preferred embodiment of the present disclosure, but not intended to fully describe the technical aspects of the present disclosure, so it should be understood that a variety of other equivalents and variations could be made thereto at the time of filing the application.

Additionally, in describing the present disclosure, when it is deemed that a detailed description of relevant known elements or functions renders the key subject matter of the present disclosure ambiguous, the detailed description is omitted herein.

The terms including the ordinal number such as “first”, “second” and the like may be used to distinguish one element from another among various elements, but not intended to limit the elements by the terms.

Unless the context clearly indicates otherwise, it will be understood that the terms “comprises” or “includes” when used in this specification, specifies the presence of stated elements, but does not preclude the presence or addition of one or more other elements.

In addition, throughout the specification it will be further understood that when an element is referred to as being “connected to” another element, it can be directly connected to the other element or intervening elements that may be present.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, depending upon the technology involved, two operations shown in successive flowchart blocks may be performed in reverse order, as a single integrated step, concurrently, or in a manner at least partially overlapping in time.

For clarity, it should be noted that the phrase “battery monitoring apparatus” refers to the claimed invention as a whole. For example, the battery monitoring apparatus may include, but need not include, a battery management system (BMS). The BMS, therefore, would not include the claimed PCB and battery pack. Conversely, the battery monitoring apparatus would include the PCB, sense wires, battery cells, and (in some embodiments) the BMS.

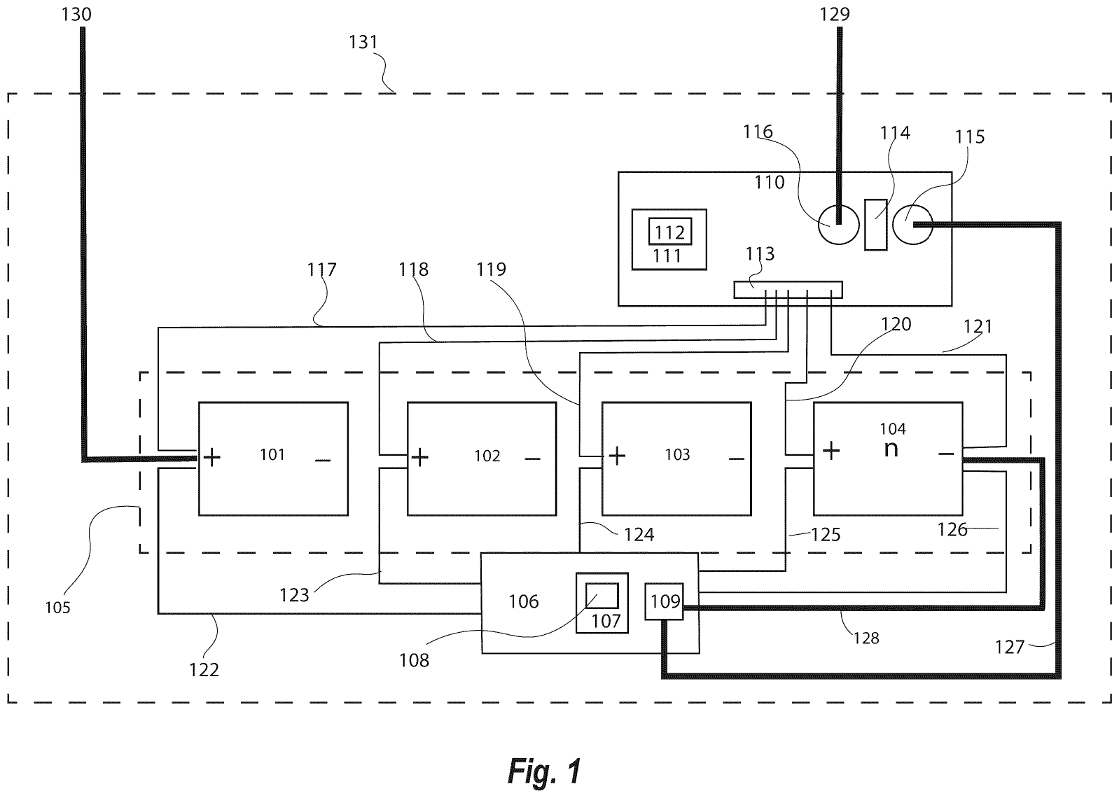

FIG. 1 depicts a schematic overview of the battery monitoring apparatus, wherein the PCB 110 is mounted within the battery case 131. FIG. 1 depicts one embodiment of the invention consisting of four battery cells and a set of five sense wires. In this embodiment one or more battery cells 101-103 (n) are used as the energy storage and conversion devices which are storing energy and providing energy to a load. The term ‘battery pack’ in this embodiment is referring to a rechargeable battery which can be a group of one or more rechargeable electrochemical cell, but this battery monitoring apparatus is capable of controlling and managing a broad range of energy storage and conversion devices such as electrochemical cells, electrolytic cells, Galvanic cells, capacitors, and fuel cells; and this [apparatus] can manage energy stored in a broad range of energy forms such as chemical, electrical, thermal, and potential energy. Examples of batteries which can be used in this system include but are not limited to lead acid, lithium air, lithium-ion, lithium-polymer, nickel-iron, nickel-zinc, nickel-metal hydride, iron-air, zinc-air, zinc-bromine, vanadium redox, sodium-sulfur, sodium-nickel chloride, lithium-iron sulfides, nickel-cadmium and flow batteries. Examples of fuel cells which can be used with this battery monitoring apparatus include but are not limited to hydrogen and hydrocarbon fuel cells. Examples of capacitors which can be used in this battery monitoring apparatus include but are not limited to variable capacitors and super-capacitors. Those skilled in the relevant arts could apply this system to other forms of energy storage or a combination of cell types or forms of energy storage devices.

According to one embodiment, the battery monitoring apparatus comprises a (BMS) 106 and sense wires 122-126 operably connecting the battery cells 101-104 to the BMS 106. The BMS may also comprise a main negative power cable connection 128 from the battery pack to the BMS. The envisioned BMS 106 will be readily apparent to those skilled in the art. The BMS 106 often comprises a microcontroller 107 and a plurality of control circuits (not shown), each connected to an associated cell 101-104 of the battery pack 105. The plurality of control circuits are operable to individually monitor the charging of the associated cell, and, when a maximum charging state is reached, to establish a shunt across the associated cell for allowing a continued charging of the remaining battery cells, while communicating to the microcontroller 107 a message representing that the maximum charging state has been reached. The plurality of control circuits is further operable during discharging of the associated cell to monitor the state of the associated cell and to inform the microcontroller when a minimum charging state has been reached, so as to cause the central controlling microcontroller to disconnect the associated cell from the load, thereby preventing excessive discharging of the cell. Said plurality of control circuits may also comprise cell balancing means and slave sensing means. Said slave sensing means may additionally comprise a microcontroller. The BMS 106 may further comprise a plurality of sensors operable to monitor, independently of the PCB 110, the temperature and voltage of the cells. The microcontroller 107 may be responsive to the temperature sensors by reducing a charging current applied to at least one of the cells if a temperature above a specified temperature is sensed.

The BMS 106 may further comprise a means for shutting down charging and discharging of the cells 109 controlled by said microcontroller 107 in the case of an overload or short circuit of the battery. The BMS 106 may further comprise a current monitoring mechanism operable to monitor the current through the battery pack, wherein the current monitoring mechanism includes a shunt resistor located in series with the cells. The BMS 106 may additionally comprise a fuse operable in case of overload or short circuit of the battery. The BMS 106 might also comprise a power supply unit operable to supply power to the central controlling microcontroller. The BMS 106 may also include a fuel gauge operable to monitor the battery current capacity.

The BMS may or may not consist of a wireless transmitter 108 operable to relay battery data to a remote device. The sense wires 122-126 will provide this data to the BMS microcontroller 107. The wireless transmitter may be integrated onto the microcontroller 107 or connected externally, and may be configured to operate at various frequency bands and power levels. Where the BMS 106 does not include a wireless transmitter, the present invention is particularly useful. For example, where the BMS 106 is lacking said wireless transmitter, the PCB 110 is operable to relay the aforementioned data wirelessly to a remote device via a wireless transmitter 112. Without the foregoing PCB 110 and presently claimed invention as a whole, the BMS would be incapable of relaying battery data to a remote device. An end user would therefore be unable to view any information relating to voltage, temperature, instantaneous current, or SoC.

Alternatively, where the BMS 106 is equipped with a wireless transmitter 108, the presently claimed invention is useful in a number of contexts. For example, where the BMS 106 comprises a wireless transmitter 108, the BMS is typically operable—with its firmware and software—to relay to an external device information relating to voltage, temperature, instantaneous current, and SoC. However, a different battery system from a different manufacturer may use a different set of firmware and software to relay the very same information to an external device. In such a situation, battery distributors selling batteries from different manufacturers will be placed in a suboptimal position wherein the end-user experience will vary depending on the manufacturer that designed the battery system.

Consider, for example, the following scenario in which an end user requires different batteries for different vehicles. Battery Distributor sells an 8V golf cart battery system to the end user, said golf battery designed by Manufacturer A. Battery Distributor then sells a different 12V boat battery system to the same user, the 12V boat battery system designed and manufactured by Manufacturer B. Although the end user purchased the battery from the same distributor, the user experience may vary when the user checks the battery status of her two vehicles. Manufacturer A may have sold a golf cart battery system to the Battery Distributor equipped with a BMS, said BMS lacking the wireless capability to monitor the battery. Manufacturer B, on the other hand, may have equipped its BMS with a wireless transmitter capable of relaying battery data. This situation is clearly disadvantageous to the Battery Distributor, whose customer is now subject to a different user experience depending on the manufacturer that designed the battery system. The present invention solves this problem by providing a means for monitoring one's battery system, regardless of the manufacturer. The Battery Distributor may now standardize this user experience by equipping the battery monitoring apparatus to each battery in its supply chain, which will relay battery status information consistently to a remote device regardless of the type of BMS that the manufacturer installed.

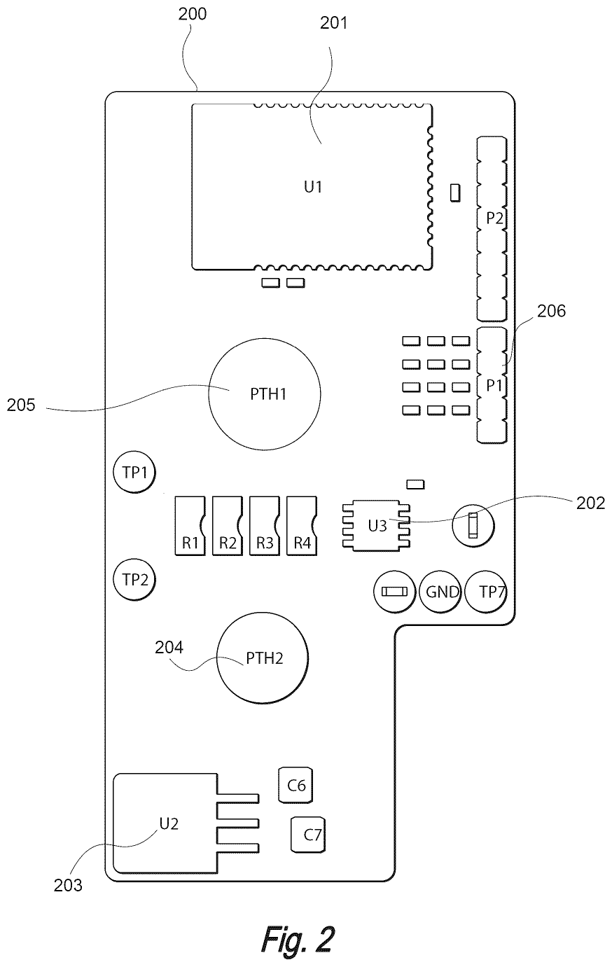

It follows that the PCB 110 is designed to operate either independently of, or in conjunction with, the BMS 106. When the PCB 110 is mounted internally within the battery case 131, the PCB 110 is operably connected to each cell 101-104 within the battery pack via a set of sense wires 117-121. It should be noted that although FIG. 1 depicts a set of at least five sense wires, any number of sense wires may be adapted to accommodate for battery packs with more or fewer cells. The PCB comprises a microcontroller 111, a wireless transmitter 112, a current measuring device 114, a first connection area 113 for receiving the sense wires 117-121, a second connection area 115 for receiving the main negative power cable 127 from the BMS 106 to the PCB 110, and a third connection area 116 for receiving the negative external battery terminal outside the case. The PCB 110 and its associated circuitry is discussed with particularity in FIGS. 2-9.

The sense wires 117-121 are connected to the battery cells and provide the microcontroller 111 with data relating to the temperature, voltage, and instantaneous current into and out from the battery pack. The number of sense wires may vary depending on the size and complexity of the battery system, but typically includes one sense wire per cell or group of cells, particularly when the PCB is mounted internally within the battery case. The sense wires are connected to the battery cells 101-104 or groups of cells 105 using a reliable and secure connection method. This may involve soldering or crimping the sense wires to the battery terminals, or using a connector or harness system to attach the sense wires to the battery cells.

Once the sense wires 117-121 are connected to the battery cells 101-104, they are routed to the microcontroller 111, which is responsible for monitoring and controlling the performance of the battery system. The sense wires 117-121 may be connected to the first connection area 113 via header pin holes. The sense wires may be soldered directly into header pin holes on the first connection area 113.

The sense wires 117-121 may be arranged in a variety of configurations. For example, the wires may be arranged in a daisy-chain configuration (not shown), with each wire connected to the next in series. Such a configuration allows for efficient routing of the sense wires and reduces the number of connections required. Alternatively, the sense wires may be arranged in a star configuration (not shown), with each wire connected to a central point or hub. This configuration allows for greater flexibility in the placement and orientation of the sense wires and may be preferable for larger or more complex battery systems.

Additionally, the sense wires 117-121 may be multiplexed to reduce the number of wires needed. Multiplexing involves sequentially connecting each sense wire to a single communication line, allowing multiple sense wires to share the same communication channel. The sense wires 117-121 may also include balancing circuits (not shown), which are used to equalize the charge of each battery cell in a series-connected battery pack. Balancing circuits typically use shunt resistors or active circuits to divert excess charge from fully charged cells to undercharged cells, ensuring that each cell is charged to the same level. The sense wires 117-121 may be made of a conductive material, such as copper or aluminum, and may be coated or insulated to prevent corrosion or short circuits. The sense wires 117-121 may also include overvoltage and undervoltage protection circuits to prevent damage to the battery cells in the event of an electrical fault or malfunction.

FIG. 2 depicts a top view of the PCB 110, 200. The PCB 110, 200 comprises a microcontroller 111, 201. The microcontroller 111, 201 is designed to provide processing and control capabilities for the battery monitoring apparatus. The microcontroller 111, 201 is operably connected to various other components of the PCB 110 200, including the sense wires 117-121 disclosed herein, the wireless transmitter 112, and current measuring device 114, using circuitry. The microcontroller 111 201 is an integrated circuit that includes a central processing unit (CPU), a memory, and GPIO pins. In the battery monitoring apparatus, the microcontroller is a key component that works in conjunction with the associated circuity to determine, from the sense wires 117-121, data concerning the voltage, SoC, temperature, and instantaneous current into and out from the battery pack, which are critical parameters for ensuring the safe and efficient operation of the battery system. The microcontroller 111 201 may additionally generate information for controlling the charging, discharging, and/or balancing of each of the battery cells based on the calculated SoC and/or State of Health, and wirelessly transmit that data through a wireless transmitter to an external device.

The microcontroller 111, 201 may selectively include a processor, an application-specific integrated circuit (ASIC), a logic circuit, a register, a communication modem, and a data processing device known in the art to execute various control logics. At least one of the various control logics of the microcontroller may be combined, and the combined control logics may be written in computer-readable coding system and recorded in computer-readable recording media. The recording media is not limited to a particular type and includes any type that can be accessed by a processor, included in a computer. Additionally, the coding system may be modulated to a carrier signal and included in a communication carrier at a particular point in time, and may be stored and executed in computers connect via a network in distributed manner. Additionally, functional programs, codes, and code segments for implementing the combined control logics may be readily inferred by artists in the technical field to which the present disclosure belongs.

The microcontroller 111, 201 operates by executing software instructions stored in its memory. These instructions are written in a programming language, such as C or Assembly, and are compiled into machine code that can be executed by the microcontroller CPU. For example, the microcontroller 111, 201 receives the raw temperature and voltage data from the respective sensors 117-121, 114 and performs calibration and compensation routines, if necessary, to account for non-linearities, offsets, and other sensor characteristics. The microprocessor 111 201 then applies the appropriate algorithms, such as lookup tables, linearization, or polynomial calculations, to derive accurate temperature and voltage values. These values are formatted and transmitted via the wireless transmitter to an external device, where they can be displayed, logged, analyzed, or used for control purposes.

The microcontroller 111 201 includes analog-to-digital converters (ADCs), which are used to convert the analog voltage signals from the sense wires into digital signals that can be processed by the microcontroller CPU. The microcontroller firmware includes algorithms and control logic that use the sense data acquired via the sense wires 117-121 to calculate the SoC, state of health, and other performance metrics. The microcontroller 111 201 may also include digital-to-analog converters (DACs), which are used to output control signals to the battery cells. These control signals may be used to balance the voltage of the battery cells, protect against overvoltage or undervoltage conditions, or control the charging or discharging of the battery system. A person having skill in the art will understand how to modify the microcontroller firmware and software to implement control logic.

The microcontroller firmware may include various control loops and algorithms that use the sense data to adjust the output control signals and maintain the battery within safe and efficient operating limits. For example, a charge control loop may adjust the charging current to maintain the voltage within a safe range, while a balancing control loop may adjust the balancing current to ensure that the voltage of each battery cell is within a certain tolerance. One skilled in the art will understand how the appropriate control loops and how to implement said control logic on the microcontroller.

The microcontroller 111 201 may further comprise a wireless transmitter 112. In one embodiment (not depicted), the wireless transmitter is a Bluetooth® radio transmitter, which is responsible for wirelessly transmitting data to a Bluetooth®-enabled device. The transmitter may be integrated onto the microcontroller chip or connected via circuitry and may be configured to operate at various Bluetooth® frequency bands and power levels. The Bluetooth® transmitter comprises a Bluetooth® module and a microcontroller. The Bluetooth® module is a wireless communication module that is capable of transmitting data over Bluetooth® protocol. The Bluetooth® module may be a standalone module or may be integrated into the microcontroller. The Bluetooth® module may operate according to various Bluetooth® standards, including but not limited to Bluetooth® Classic and Bluetooth Low Energy (BLE). The microcontroller is responsible for controlling the operation of the Bluetooth® module and for providing the data to be transmitted over the Bluetooth® connection.

The microcontroller 111 201 receives data from the sense wires 117-121 and current measuring sensor 114 202. The microcontroller 111 201 processes the data and prepares the data for transmission over the Bluetooth connection. The microcontroller 111 201 then sends said data to the Bluetooth module, which transmits the data wirelessly to a remote device that is paired with the Bluetooth transmitter (not shown).

The Bluetooth transmitter may include various security features to protect the data transmitted over the Bluetooth connection. The Bluetooth transmitter may use various encryption techniques to secure the data and may require authentication before allowing access to the data. The Bluetooth transmitter may also include various power-saving features to conserve battery life. For example, the Bluetooth transmitter may enter a ‘low power’ mode known to those skilled in the art, when not in use, or may adjust the transmission power based on the distance to the remote device.

In another embodiment (not shown), the Bluetooth radio transmitter may be supplanted with a wireless 802.11 transmitter for use with the microcontroller 111 201. The wireless 802.11 transmitter comprises an 802.11 module and a microcontroller. The wireless 802.11 module is a wireless communication module that is capable of transmitting data over the 802.11 wireless networking protocol. The wireless 802.11 module may be standalone module or may be integrated into the microcontroller. The wireless 802.11 module may operate according to various 802.11 standards, including but not limited to 802.11a, 802.11b, 802.11n, and 802.11ac.

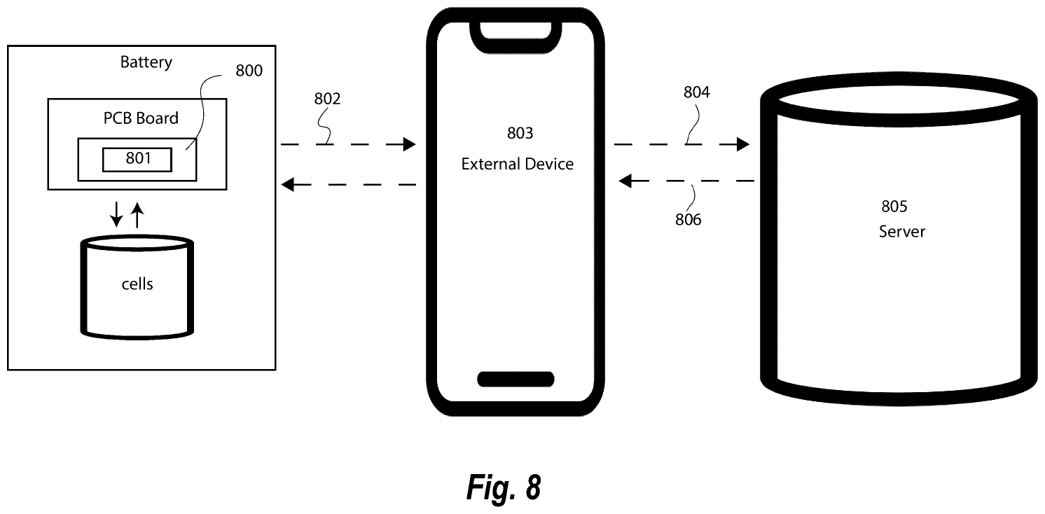

The microcontroller 111 201 is responsible for controlling the operation of the wireless 802.11 module and for providing the data to be transmitted over the wireless 802.11 connection. In one embodiment, the microcontroller 111 201 receives data from the sense wires 117-121 and current measuring sensor 114 202, processes the data, and prepares it for transmission over the wireless 802.11 connection. The microcontroller then sends the data to the wireless 802.11 module, which transmits the data wireless to a remote device that is connected to the same wireless network, exemplified further in FIG. 8.

The microcontroller 111 201 may receive commands or other instructions from a remote device via the wireless 802.11 connection. The microcontroller processes the commands and performs the necessary actions based on the instructions received. For example, the wireless transmitter can receive a command from a smartphone commanding the microcontroller to power one or more of its output pins, illustrated further in FIG. 8. The then-activated microcontroller output in can then communicate with the BMS 106, for example, by tripping a BMS protection function if the output pin of the PCB 110 200 is connected to the BMS 106. In the alternative, the output pin could directly control a large switch or relay that cuts off the main power connection of the battery pack. A command from a remote device could then reverse this action by deactivating the very same output pin.

The wireless 802.11 transmitter may include various security features to protect the data transmitted over the wireless 802.11 connection. The wireless 802.11 transmitter may use various encryption techniques to secure the data and may require authentication before allowing access to the data. The wireless 802.11 transmitter may also include various power-saving features to conserve battery life. For example, the wireless 802.11 transmitter may enter a ‘low power’ mode known to those skilled in the art when not in use or may adjust the transmission power based on the distance to the remote device.

The PCB further comprises a current measuring sensor 114 202, which is capable of measuring the electrical current flowing through the PCB via the main negative power cable or other connection means 127. The current measuring sensor 114 202 is designed to be mounted directly onto the PCB 110 200. The current measuring sensor 114 202 be a resistive shunt, a Hall Effect sensor, or any other type of sensor capable of accurately measuring electrical current. The current measuring sensor typically comprises a shunt resistor, an operational amplifier, and an analog-to-digital converter (ADC). The shunt resistor is connected in series with the battery to measure the current flowing through it. The shunt resistor is selected based on the expected maximum current and the desired accuracy so that the voltage drop across the shunt resistor is predictably proportional to the current flowing through it.

The operational amplifier amplifies the electrical signal generated by the sensor to deliver it to the ADC. The amplified signal from the ADC is then processed by a microcontroller, or other signal processing unit, which converts the signal into a usable format for monitoring and analysis. The operational amplifier is configured as a non-inverting amplifier with a gain determined by the feedback resistor and the input resistor. The output voltage of the operational amplifier is proportional to the voltage drop across the shunt resistor, and hence proportional to the current flowing through the battery. The resolution and sampling rate of an ADC is selected based on the desired accuracy and the maximum frequency of the current signal.

In one embodiment the current measuring sensor 114 202 is powered by the battery voltage and consumes very little power. The device can be integrated as a separate module or as part of a larger circuit. The sensor can be calibrated using a known current source or by comparing the readings with a reference instrument. The current measuring sensor may be used to optimize the battery pack performance and prevent overcharging and over-discharging. The sensor provides an accurate and reliable measurement of the current flowing through the battery pack, which can be used to adjust the charging and discharging parameters of the BMS. By optimizing the battery pack performance, employment of the sensor in the apparatus can extend the life span of the battery pack and improve the efficiency.

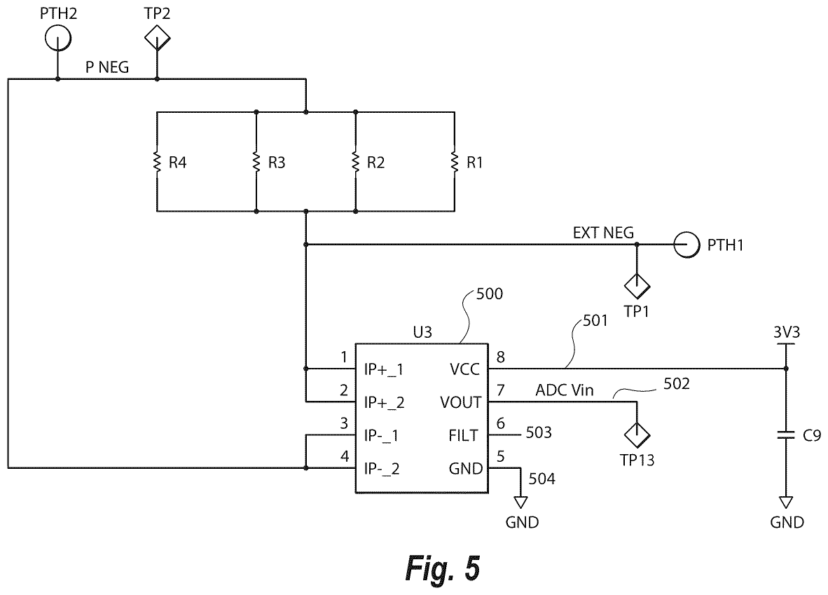

The current measuring sensor 114 202 may include power management features, such as a power-saving mode, to conserve power and extend battery life. The current measuring sensor is discussed with particularity in FIG. 5, where it is illustratively depicted as a Hall Effect sensor. It should be noted that other current measuring devices are envisioned. The Hall Effect sensor is provided merely as an example of a current measuring sensor.

In one embodiment, the PCB comprises a voltage regulator 203, designed to provide power to the microprocessor 111 201. A voltage regulator 203 typically comprises the following components: an input voltage sensing circuit, a control circuit, a power stage, and a feedback loop. The input voltage sensing circuit may include voltage dividers, comparators, and filters to accurately sense the input voltage level. The sensing circuit provides this information to the control circuit for further processing.

The control circuit is capable of generating a control signal based on the input voltage and a reference voltage. The reference voltage is a predefined voltage level that represents the desired output voltage. The control circuit can employ operational amplifiers, comparators, or other suitable components to compare the input voltage with the reference voltage and generate the control signal accordingly. The control circuit may also include compensation circuits to improve stability and response time.

The power stage is responsible for adjusting the output voltage based on the control signal received from the control circuit. The power stage may include transistors, switches, or other power devices to regulate the output voltage. It may utilize switching techniques, such as pulse-width modulation (PWM), to efficiently control the power flow and receive the desired output voltage level.

The feedback loop continuously monitors the output voltage and provides feedback to the control circuit. The feedback loop typically includes a voltage divider, an error amplifier, and a compensator. The voltage divider senses the output voltage and provides a feedback signal to the error amplifier. The error amplifier compares the feedback signal with the reference voltage and generates an error signal. The compensator processes the error signal to improve stability and response characteristics. The feedback loop ensures precise regulation by continuously adjusting the control signal based on the difference between the output voltage and the reference voltage.

The voltage regulator 203 may achieve a high level of efficiency by minimizing power losses through efficient power conversion techniques and minimizing quiescent current. It provides stability by employing compensation techniques, such as pole-zero placement, to optimize regulator response and stability margins. It should be noted that the voltage regulator can be implemented as an integrated circuit (IC) or discrete component, depending on the preferences of a person having skill in the art.

The PCB 110 200 illustratively comprises a second connection area 115 204 (PTH2) (illustrated as a bolt hole) for receiving the main negative power cable 127 from the BMS 106 to the PCB 110, 200. The PCB also comprises a third connection area 116 205 (PTH1) for the negative external battery pack terminal outside of the battery case 129 to go out to other equipment that is powered by the battery system. However, any other secure fastening arrangement that ensures a robust and stable connection may be implemented so long as said fastening arrangement connects the main negative power cable from the BMS to the PCB; and the negative external battery system terminal is external to the battery case 131.

In one embodiment, the PCB 110 200 comprises a first connection area 206 (P1) for receiving the sense wires 117-121. P2 depicts a set of connection points where firmware can be uploaded or updated. The following components will be required to connect the sense wires to the connection area: a header connector, sense wire connectors, and a secure fastening arrangement. The header connector is designed to fit into the pinholes of the first connection area 206. It may include pins or sockets that align with and properly fit into the corresponding pinholes on the PCB. The header connector ensures accurate and secure connection between the sense wires and the battery cells. The sense wire connectors are designed to attach to the sense wires, which are responsible for measuring various battery cell parameters. The sense wire connectors may include terminals, pins, or sockets that securely hold the sense wires and provide a reliable electrical connection. The sense wire connectors can be made of conductive material such as copper or aluminum to ensure efficient signal transmission. The secure fastening arrangement ensures a stable and robust connection between the header connector and the sense wire connectors. It may include any number of fasteners, such as screws, bolts, clamps, or any other suitable means of attachment. The secure fastening arrangement prevents accidental disconnection, ensuring a reliable and continuous connection between the sense wires and the PCB.

In some embodiments, the first connection area 206 may include additional features such as strain relief mechanisms, protective covers, or insulating materials. These features provide mechanical support, strain relief, and insulation to safeguard the connection against external factors and prevent short circuits or damage to the electrical components. In totality, connecting the sense wires to the connection are in this way enables a secure and reliable connection between the sense wires and the connection points on the PCB. It should be noted that the addition or subtraction of header pinholes may be necessary where the battery monitoring apparatus is designed to monitor a varying number of battery cells. One skilled in the art would understand how to modify the connection area to accommodate any number of battery cells.

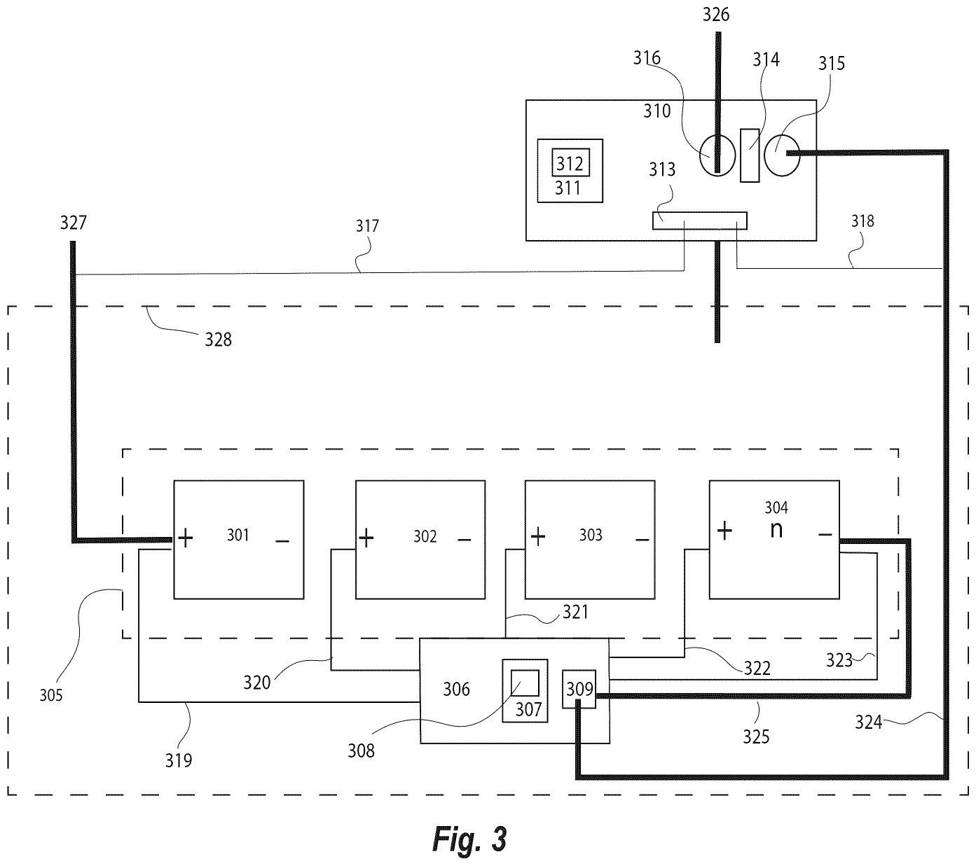

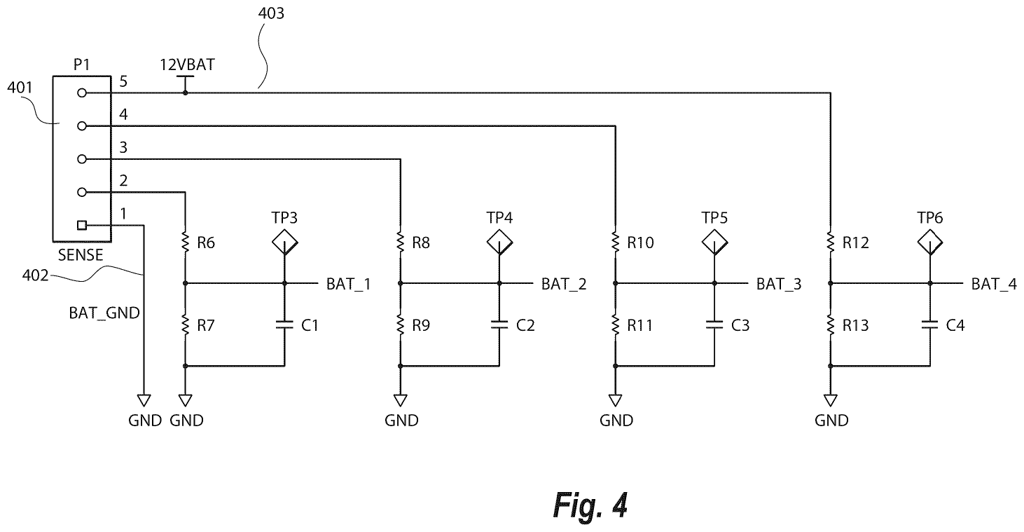

FIG. 3 depicts a schematic overview of the battery monitoring apparatus, wherein the PCB 110 200 310 is mounted externally on the battery case 328 as an attachment or accessory. To optimize space utilization or enable convenient access to the PCB 310, it may be desirable to attach the PCB directly to the negative external battery system terminal 326 located outside the battery case. The PCB 310 securely attaches, either directly or indirectly, to the battery case 328 according to any number of methods commonly known in the art. In FIG. 3, the PCB 310 is illustratively attached via a bolt hole, or third connection area 116 316 in the PCB, where the PCB 310 is operably connected to the negative external battery system terminal outside the case 326. The main negative power cable from the BMS 324 is operably connected the second connection area 115 315, illustrated as a bolt hole, on the PCB 310.

Where the PCB 310 is connected externally on the battery system terminal 326 as in FIG. 3, it should be noted that it is not necessary to connect sense wires to each individual battery cell 301-304 within the battery. Further, the structure and components of the PCB will remain as described in FIG. 1, save for the circuitry depicted in FIG. 4. It should be noted that other means of securing the PCB to the battery system are envisioned and will be readily apparent to one skilled in the art.

FIG. 4 illustrates the circuitry connecting the sense wires 117-121 to the connection area 113 206 313 401 on the PCB 110 200 wherein the PCB is mounted within the battery case 131. Ref 402 depicts circuitry connecting a first sense wire to battery ground (BAT_GND). Circuitry is depicted wherein a second sense wire is connected to two resistors (R6 and R7), the resistors connected in series, leading to ground. Connections for a capacitor, test point, and first battery cell are also depicted. The configuration of the foregoing circuitry continues for each successive sense wire 117-121, 317-318 connection needed for monitoring individual cells 101-104, 301-304 of the battery 105 305. Where the PCB 310 is connected outside of the battery case 328, a sense wire need not be connected to every cell in order to monitor the battery pack. Instead, only two sense wires 317 318 will be utilized. Where the PCB is mounted externally, Ref 402 will connect to the negative terminal outside of the battery housing. Ref 403 will connect to the positive battery terminal outside of the housing.

FIG. 5 depicts the circuitry design for the Hall Effect sensor, a type of current measuring sensor 114 202 314. The Hall Effect sensor 500 comprises the following components: a hall effect element, a voltage common collector circuit 501, an output voltage circuit 502, a filtering circuit 503, and a ground connection 504. The Hall Effect sensor is typically made of a semiconductor material commonly known in the art. The hall effect element is positioned in close proximity to the magnetic field to be measured. When a magnetic field is present, the hall effect element generates an analog voltage known as the Hall voltage. The Hall voltage is directly proportional to the magnetic field strength and the current flowing through the conductor.

The voltage common collector circuit (VCC) 501 ensures a stable operating voltage for the Hall Effect sensor 500. It typically includes a common collector amplifier configuration. The common collector amplifier provides voltage buffering and impedance matching to minimize the loading effect on the Hall effect element. This configuration helps maintain a consistent and reliable power supply for the Hall effect sensor 500, ensuring accurate measurements.

The output voltage circuit 502 is responsible for processing the Hall voltage generated by the Hall effect element and generating an output signal. It may include amplifiers, voltage dividers, and level shifters to adapt the Hall voltage to the desired output range or signal format. The output voltage circuit can be designed to provide analog voltage output, digital output, or any other suitable representation proportional to the measured magnetic field.

The filtering circuit 503 is employed to remove noise or interference from the output signal. It can include passive or active filtering elements such as resistors, capacitors, inductors, or operational amplifiers. The filtering circuit 503 helps ensure a clean and reliable output signal, enhancing the accuracy of the measured magnetic field.

The ground connection (GND) 504 provides the necessary electrical grounding for the Hall Effect sensor. It ensures proper reference potential and helps mitigate electrical noise and interference. The ground connection can be physically connected to the battery ground, or any suitable grounding point, ensuring a stable and reliable operation of the sensor.

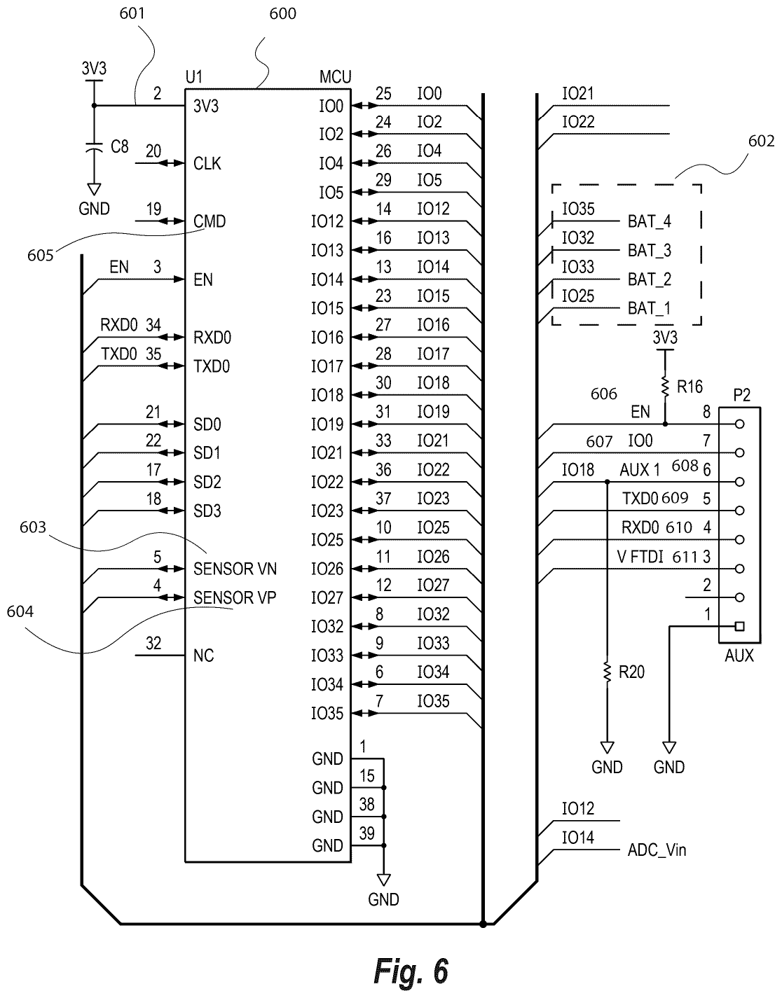

FIG. 6 depicts the envisioned circuitry of the PCB microcontroller 111 201 311 600. The microcontroller 600 receives power from the voltage regulator at Ref. 601. Ref. 602 depicts circuitry where the microcontroller is connected to four battery cells via four IO pins, illustratively, 1O25, 1O32, IO33, and IO35. However, notably, the microcontroller 600 comprises a sensor VN interface 603. The Sensor VN interface 603 provides the connection for the negative terminal of an analog sensor for the microprocessor to sense and measure analog signals by receiving the voltage or current output from the battery. The sensor VP interface 604 provides the connection for the positive terminal of an analog sensor for the microprocessor to accurately sense and measure analog signals. The microcontroller also comprises a CMD interface 605. The CMD interface 605 enables the transmission of command and control signals between the microprocessor 111 201 311 600 and the BMS 106 306. The CMD interface 605 typically includes input/output buffers, address decoding circuits, and control logic to facilitate the transmission and reception of commands. The microcontroller also comprises an EN interface 606 that allows for power management and control of the microprocessor. It typically includes power enable control signals that determine the on/off state of the microprocessor. The 1O0 interface 607 provides a general-purpose input/output (GPIO) pin on the microprocessor. The AUX 1 interface 608 is an auxiliary interface that can be utilized for various purposes. It may function as an additional GPIO pin, a specific-purpose input or output pin, or a communication interface with specific protocols. The AUX 1 interface 608 enhances the flexibility and expandability of the microprocessor system. The TXD0 609 and RXD0 610 interfaces are used for serial data communication, enabling the microprocessor to transmit and receive data using a specific serial protocol, such as the Universal Asynchronous Receiver-Transmitter. The TXD0 interface 609 serves as the transmitter, while the RXD0 interface 610 serves as the receiver. The Future Technology Devices International (FTDI) interface is a specialized interface that allows the microprocessor to communicate with an FTDI chip or module. It provides a connection for USB communication, enabling the microprocessor to interface with USB devices or connect to a computer system. Moreover, ADC_Vin depicts one option for Hall Effect sensor connection. All other circuitry is illustrated using universal symbols and is readily understood by one having skill in the art.

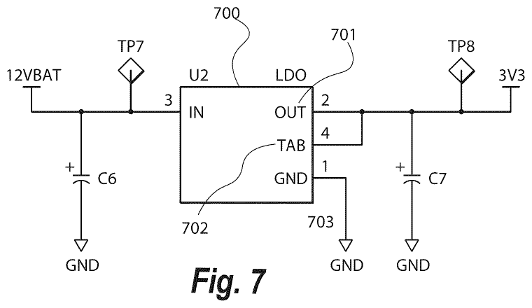

FIG. 7 depicts circuitry of a voltage regulator 700 that supplies power to the microprocessor 111 201 311 600. It should be noted that other types of voltage regulators are envisioned, including a linear regulator or switching regulator. The voltage regulator 700 is illustratively a low dropout regulator with circuitry comprising the OUT 701, TAB 702, and GND circuits 703. The OUT 701 circuit is responsible for regulating the output voltage of the regulator. It supplies a stable 3.3V output to the microprocessor 111 201 311 600. The OUT circuit 701 may include voltage references sources, error amplifiers, pass transistors, and feedback networks. The voltage reference sources generate a stable reference voltage against which the output voltage is compared. The error amplifiers monitor the output voltage and generate control signals to adjust the conduction of the pass transistor, maintaining the desired output voltage, which is 3.3V in this particular example. The feedback network ensures accurate feedback of the output voltage to the error amplifiers, facilitating precise regulation. In operation, the OUT circuit 701 regulates the output voltage by comparing it with the reference voltage and adjusting pass transistor conduction accordingly.

The TAB circuit 702 provides thermal dissipation and electrical isolation for the voltage regulator 700. It typically includes a thermal pad or heat sink connected to the active components to dissipate excess heat generated during operation. The TAB circuit 702 may also include insulation layers or isolation techniques to ensure electrical separation between the regulator and other circuitry or components, minimizing potential interference.

FIG. 8 is a flowchart depicting an example of communication between the battery cells 101-104 301-304, the PCB 110 200 310, an external device 803, and external server 805. As discussed, battery data 802 relating to temperature, voltage, instantaneous current into the battery, instantaneous current out of the battery, SoC, battery identification information, lifetime charge and discharge cycles, historic voltage information, and any number of battery parameters may be transmitted to an external device 803 via the wireless transmitter 112 312 of the microprocessor 111 201 311 800. Battery data 802, including various parameters and measurements, may be stored on microprocessor memory 801 and/or stored remotely on a storage device 803, 805. In addition, the microprocessor may implement control logic 806 to control the battery system. For example, the control logic may turn the battery system on and off. Said control logic could independently turn on and off charging and discharging capabilities of the battery system. An end user could illustratively turn off battery system charging capability only. Or, in the alternative, the end user could turn off the discharging capability only, rendering the battery system in a status where it could only be charged but not discharged, or vice versa. Both charging and discharging could also be turned off. Transistor and relay alternatives could also be controlled by logic.

A “storage device” is any tangible device that can retain and store instructions for use by a microprocessor. Without limitation, a computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disc (DVD), memory stick, floppy disc, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

The battery system data 802 may be transmitted to an external device 803, such as a computer. A computer may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database. As is well understood in the art of computer technology, performance of control logic and the storage of battery data may be distributed among multiple computers and/or between multiple locations. Alternatively, the computer or external device may be located in a cloud, even though it is not shown in a cloud in FIG. 8. On the other hand, computer or external device is not required to be in a cloud except to any extent as may be affirmatively indicated.

Control logic and firmware instructions 806 are typically loaded onto the microprocessor 800 to cause a series of operational steps to be performed by said microprocessor and thereby effect the control logic. The firmware instructions and associated data 806, are accessed by the PCB microprocessor 111 311 600 800 to measure, transmit data, control, and direct performance of the battery cells and system. In the microprocessor, at least some of the instructions for collecting the performance data may be stored in a public cloud, private cloud, remote server, or persistent storage. Moreover, battery data 802 relating to the temperature, voltage, instantaneous current into and out of the battery system, SoC, battery identification information, lifetime charge and discharge cycles, historic voltage information, and any number of battery parameters may be stored in the memory of the microprocessor, a public cloud, private cloud, remote server, or persistent storage.

PERSISTENT STORAGE is any form of non-volatile storage for computers that is now known or to be developed in the future. The non-volatility of this storage means that the stored data is maintained regardless of whether power is being supplied to a computer and/or directly to persistent storage. Persistent storage may be a read only memory (ROM), but typically at least a portion of the persistent storage allows writing of data, deletion of data and re-writing of data. Some familiar forms of persistent storage include magnetic disks and solid state storage devices.

REMOTE SERVER 805 is any computer system that serves at least some data and/or functionality to the external device 803 or microprocessor 111 311 600 800. Remote server 805 may be controlled and used by the same entity that operates the PCB and its software client. Remote server 805 represents the machine(s) that collect and store helpful and useful data for use by other computers, such as the external device 803 or microprocessor 800. For example, where microprocessor is designed and programmed to provide a recommendation based on historical data, then this historical data may be provided to microprocessor 800 from a remote database, not depicted, of remote server 805.

PUBLIC CLOUD is any computer system available for use by multiple entities that provides on-demand availability of computer system resources and/or other computer capabilities, especially data storage (cloud storage) and computing power, without direct active management by the user. Cloud computing typically leverages sharing of resources to achieve, coherence, and access economies of scale. The direct and active management of the computing resources of public cloud is performed by the computer hardware and/or software of cloud orchestration module. The computing resources provided by public cloud are typically implemented by virtual computing environments that run on various computers making up the computers of host physical machine set, which is the universe of physical computers in and/or available to public cloud. The virtual computing environments (VCEs) typically take the form of virtual machines from virtual machine set and/or containers from container set. It is understood that these VCEs may be stored as images and may be transferred among and between the various physical machine hosts, either as images or after instantiation of the VCE. Cloud orchestration module manages the transfer and storage of images, deploys new instantiations of VCEs and manages active instantiations of VCE deployments. Gateway is the collection of computer software, hardware, and firmware that allows public cloud to communicate through WAN.

PRIVATE CLOUD is similar to public cloud, except that the computing resources are only available for use by a single enterprise. While private cloud may be in communication with WAN, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds.

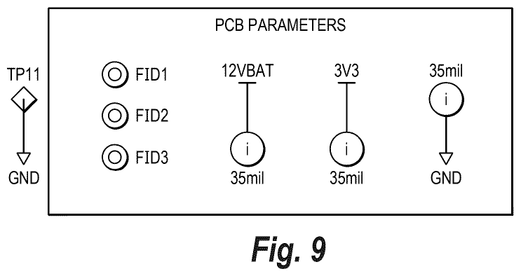

FIG. 9 depicts attributes of the PCB substrate itself. For example, the electrically conductive traces, circuitry, on the board are illustratively shown as 35 mil wide.

The system described above can use dedicated processor systems, micro controllers, programmable logic devices, or microprocessors that perform some or all of the communication and battery monitoring operations. Some of the operations described above may be implemented in software or firmware, and other operations may be implemented in hardware.

For the sake of convenience, the operations are described as various interconnected functional blocks or distinct software modules. This is not necessary, however, and there may be cases where these functional blocks or modules are equivalently aggregated into a single logic device, program or operation with unclear boundaries. In any event, the functional blocks and software modules or described features can be implemented by themselves, or in combination with other operations in either hardware or software.

Having described and illustrated the principles of the invention in a preferred embodiment thereof, it should be apparent that the invention may be modified in arrangement and detail without departing from such principles. Claim is made to all modifications and variation coming within the spirit and scope of the following claims.

What is claimed is:

1. A battery monitoring apparatus and battery pack comprising:
a battery pack;
a set of at least two sense wires operably connecting a set of battery cells in the battery pack to a printed circuit board (PCB) mounted inside of a battery case;
the PCB operably connected to the set of at least two sense wires, the PCB comprising:
a memory connected to a hardware microprocessor, said memory storing:
computer-executable instructions,
historic voltage information,
lifetime charge-and-discharge cycles, and
identifying information of the battery pack;
a current measuring sensor;
a microprocessor to execute the computer executable instructions configured to:
determine, from the set of at least two sense wires, data associated with a voltage of the battery pack;
determine, from the set of at least two sense wires, a state charge of the battery pack;
determine, from the set of at least two sense wires, a temperature of the battery pack;
determine, from the current measuring sensor, an instantaneous current into the battery pack; and
determine, from the current measuring sensor, an instantaneous current out from the battery pack;
a wireless transmitter configured to:
receive, from the microprocessor, the voltage of the battery pack, instantaneous current into the battery pack, the instantaneous current into and out from the battery pack, and the state charge of the battery pack;
receive, from the memory, the historic voltage information, the lifetime charge-and-discharge cycles, and the identifying information of the battery pack; and
transmit, to a wireless receiver on a remote device, the voltage of the battery pack, the instantaneous current into and out of the battery pack, the state charge of the battery pack, the historic voltage information, the lifetime charge-and-discharge cycle, and the identifying information of the battery pack.

2. The battery monitoring apparatus of claim 1, wherein the PCB is mounted internally on the surface of the battery case via a negative battery terminal.

3. The battery monitoring apparatus of claim 1, further comprising a battery management system (BMS).

4. The battery monitoring apparatus of claim 1, the PCB further comprising a power cutoff device.

5. The battery monitoring apparatus of claim 1, wherein the PCB enters a state of reduced power consumption of less than 15 mA responsive to detecting an absence of the wireless receiver connected to the microprocessor.

6. The battery monitoring apparatus of claim 1, wherein the PCB “wakes” when the wireless receiver is connected to the microprocessor, the PCB drawing no more than 150 mA of power from the battery to which it is operably connected.

7. The battery monitoring apparatus of claim 1, the PCB further comprising a voltage regulator that supplies power to the PCB microprocessor.

8. A battery monitoring apparatus and battery pack comprising:
a battery pack;
a set of at least two sense wires;
a PCB operably connected outside of a battery case to the set of at least two sense wires, the PCB comprising:
a memory connected to a hardware microprocessor, said memory storing:
computer-executable instructions,
historic voltage information,
lifetime charge-and-discharge cycles, and
identifying information of the battery pack;
a current measuring sensor;
a microprocessor to execute the computer executable instructions configured to:
determine, from the set of at least two sense wires, data associated with a voltage of the battery pack
determine, from the set of at least two sense wires, a state charge of the battery pack;
determine, from the set of at least two sense wires, a temperature of the battery pack;
determine, from the current measuring sensor, an instantaneous current into the battery pack;
determine, from the current measuring sensor, an instantaneous current out from the battery pack;
a wireless transmitter configured to:
receive, from the microprocessor, the voltage of the battery pack, instantaneous current into the battery pack, the instantaneous current into and out from the battery pack, and the state charge of the battery pack;
receive, from the memory, the historic voltage information, the lifetime charge-and-discharge cycles, and the identifying information of the battery pack; and
transmit, to a wireless receiver on a remote device, the voltage of the battery pack, the instantaneous current into and out of the battery pack, the state charge of the battery pack, the historic voltage information, the lifetime charge-and-discharge cycle, and the identifying information of the battery pack.

9. The battery monitoring apparatus of claim 8, wherein the PCB is mounted externally on the surface of the battery case via a negative external battery terminal.

10. The battery monitoring apparatus of claim 8, wherein a first sense wire from the set of at least two sense wires is operably connected to a positive external battery terminal.

11. The battery monitoring apparatus of claim 8, wherein a second sense wire from the set of at least two sense wires is operably connected to the negative external battery terminal.

12. The battery monitoring apparatus of claim 8, further comprising a battery management system (BMS).

13. The battery monitoring apparatus of claim 8, the PCB further comprising a power cutoff device.

14. The battery monitoring apparatus of claim 8, wherein the PCB enters a state of reduced power consumption of less than 15 mA responsive to detecting an absence of the wireless receiver connected to the microprocessor.

15. The battery monitoring apparatus of claim 8, wherein the PCB “wakes” when the wireless receiver is connected to the microprocessor, the PCB drawing no more than 150 mA of power from the battery to which it is operably connected.

16. The battery monitoring apparatus of claim 8, the PCB further comprising a voltage regulator that supplies power to the PCB microprocessor.
